(19) United States
(12) Patent Application Publication
(10) Pub. No.: US 2025/0038741 A1
(43) Pub. Date: Jan. 30, 2025

(54) METHOD AND XR DEVICE FOR HANDLING DISPLAY DEVICE IN XR ENVIRONMENT

(71) Applicant: SAMSUNG ELECTRONICS CO., LTD., Suwon-si (KR)

(72) Inventors: Ankur Harkawat, Bangalore (IN); Aakash Arora, Bangalore (IN); Vivek Sridhar, Bangalore (IN)

(73) Assignee: SAMSUNG ELECTRONICS CO., LTD., Suwon-si (KR)

(21) Appl. No.: 18/783,038

(22) Filed: Jul. 24, 2024

Related U.S. Application Data
(63) Continuation of application No. PCT/KR2024/010524, filed on Jul. 22, 2024.

(30) Foreign Application Priority Data
Jul. 24, 2023 (IN) 202341049725
Jul. 1, 2024 (IN) 202341049725

(51) Int. Cl. H03K 7/08; G06T 19/00

(52) U.S. Cl. CPC H03K 7/08; G06T 19/006

(57) ABSTRACT

A method for handling a display device in an extended reality (XR) environment, includes: obtaining at least one media of a scene comprising a plurality of display devices; determining at least one pixel group comprising locations of the plurality of display devices in the at least one media; determining at least one parameter based on the at least one determined pixel group, wherein the at least one parameter comprises at least one of a frequency and a duty cycle; extracting a pulse width modulation (PWM) signal corresponding to the display device from the plurality of display devices based on the at least one parameter; and recognizing the display device from the plurality of display devices by correlating the extracted PWM signal with an identifier (ID) of the display device stored in at least one memory of the XR device.

### CROSS REFERENCE TO RELATED APPLICATIONS

This application is a by-pass continuation application of International Application No. PCT/KR2024/010524, filed on Jul. 22, 2024, which is based on and claims priority to Indian Complete Application 202341049725, filed on Jul. 1, 2024, and Indian Provisional Application 202341049725, filed on Jul. 24, 2023, in the Indian Intellectual Property Office, the disclosures of which are incorporated by reference herein their entireties.

### BACKGROUND

### 1. Field

The disclosure relates to identifying and controlling display devices in an Internet of Things (IoT) environment, and more particularly, to identifying and controlling the display devices using pulse width modulation (PWM) detection and frequency analysis, when a user is wearing an Extended Reality (XR) device (e.g., video see-through (VST) device).

### 2. Description of Related Art

Currently, typical users have many IoT devices in his vicinity. However, it can be very difficult for the user to on-board and control the IoT devices while wearing an XR device (e.g., VST device).

FIG. 1 illustrates an example scenario (100) in which a user sees a combined view to experience Augmented Reality (AR). ‘Video See-Through (VST)’ is one of the technologies used for providing an AR experience in a head-mounted display (HMD). The VST may have multiple cameras. The camera view of the real world through a display may be combined with computer-generated content (e.g., virtual world). The user may see the combined view to experience AR.

FIG. 2 and FIG. 3 illustrate example scenarios (200 and 300) in which the user sees through the XR device (e.g., the VST device) 210. As shown in FIG. 2, the user wearing the XR device 210 to view the multiple devices 220a and 220b (e.g., two laptops, mobile, and tablets). The user view 240 through the XR device 210 is shown in FIG. 2 and FIG. 3. However, it can be very difficult for the user to on-board and control the multiple devices 220a and 220b through the XR device 210 while wearing the XR device 210.

In another example, the user may have many IoT devices and appliances (e.g., many mobiles, laptops, and smart lights) around the user in a living room. It is very difficult to on-board and control the IoT devices through the XR device 210 while wearing the XR device 210.

The above information is presented as background information only to help the reader to understand the present invention. Applicants have made no determination and make no assertion as to whether any of the above might be applicable as prior art with regard to the present application.

### SUMMARY

This summary is provided to introduce a selection of concepts, in a simplified format, that are further described in the detailed description of the invention. This summary is neither intended to identify essential inventive concepts of the invention nor is it intended for determining the scope of the invention.

Provided is a method for handling a display device in an extended reality (XR) environment. The method may include obtaining, by an XR device, at least one media of a scene comprising a plurality of display devices. The method may include determining, by the XR device, at least one pixel group comprising locations of the plurality of display devices in the at least one media. The method may include determining, by the XR device, at least one parameter based on the at least one determined pixel group, wherein the at least one parameter comprises at least one of a frequency and a duty cycle. The method may include extracting, by the XR device, a pulse width modulation (PWM) signal corresponding to the display device from the plurality of display devices based on the at least one parameter. The method may include recognizing, by the XR device, the display device from the plurality of display devices by correlating the extracted PWM signal with an identifier (ID) of the display device stored in at least one memory of the XR device.

Provided is an extended reality (XR) device. The XR device may include at least one processor. The XR device may include at least one memory. The XR device may include a pulse width modulation (PWM) based display device controller, coupled with the at least one processor and the at least one memory, configured to cause the XR device to obtain at least one media of a scene comprising a plurality of display devices. The XR device may determine at least one pixel group comprising locations of the plurality the locations in the at least one obtained media. The XR device may determine at least one parameter based on the at least one determined pixel group. The at least one parameter comprises at least one of a frequency and a duty cycle. The XR device may extract a pulse width modulation (PWM) signal corresponding to the display device from the at least one parameter. The XR device may and recognize the display device from the plurality of display devices by correlating the extracted PWM signal with an identifier (ID) of the display device stored in the at least one memory of the XR device.

According to an embodiment of the disclosure, disclosed herein is a non-transitory computer-readable storage medium storing instructions. The instructions, when executed by at least one processor, cause the XR apparatus to perform the method.

### BRIEF DESCRIPTION OF THE DRAWINGS

The embodiments disclosed herein are illustrated in the accompanying drawings, throughout which like reference letters indicate corresponding parts in the various figures. The embodiments herein will be better understood from the following description with reference to the drawings, in which:

FIG. 1 illustrates an example scenario in which a user sees a combined view to experience Augmented Reality (AR);

FIG. 2 and FIG. 3 illustrate example scenarios in which a user view through an extended reality (XR) device (e.g., video see-through (VST) device);

FIG. 4A and FIG. 4B illustrate how modern displays adjust their brightness;

FIG. 5 illustrates various hardware components of the XR device, according to the embodiments as disclosed herein;

FIG. 6 illustrates an example scenario in which a screen with a unique pulse width modulation (PWM) signal is explained, according to the embodiments as disclosed herein;

FIG. 7 illustrates various components of a PWM based display device controller of the XR device interacting with a display device (e.g., a LED device) and a cloud server, according to the embodiments as disclosed herein;

FIG. 8 is a flow chart illustrating a PWM signal extraction operation, according to the embodiments as disclosed herein;

FIG. 9 is a flow chart illustrating a frequency analysis operation, according to the embodiments as disclosed herein;

FIG. 10 illustrates a process of identifying and controlling the display devices using PWM detection and frequency analysis, when a user is wearing the XR device (e.g., VST device), according to the embodiments as disclosed herein;

FIG. 11 illustrates a process of identifying and controlling the display devices using the PWM detection and frequency analysis, when the user is wearing the XR device to access the LED display device (e.g., a laptop, a mobile device), according to the embodiments as disclosed herein;

FIG. 12 illustrates a process of identifying and controlling the display devices using the PWM detection and frequency analysis, when the user is wearing the XR device to control a LED based display device (e.g., a smart bulb, a TV), according to the embodiments as disclosed herein;

FIG. 13 illustrates an example scenario, wherein the user controls a laptop or smart phone, when the user is using the XR device, according to the embodiments as disclosed herein;

FIG. 14 is a flow chart illustrating a method for handling a display device in the XR environment based on an extracted PWM signal, according to the embodiments as disclosed herein;

FIG. 15 is a flow chart illustrating a method for handling a display device in the XR environment based on a pass-through mode, according to the embodiments as disclosed herein; and

FIG. 16 is a flow chart illustrating a method for handling a display device in the XR environment based on a detected PWM signal, according to the embodiments as disclosed herein.

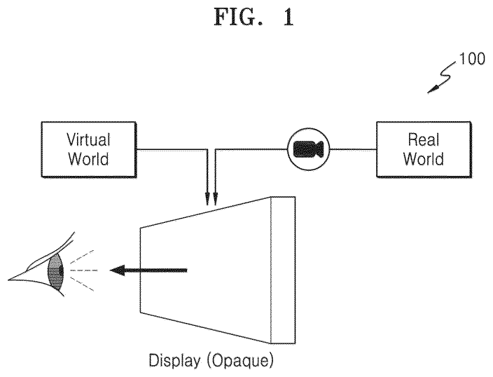

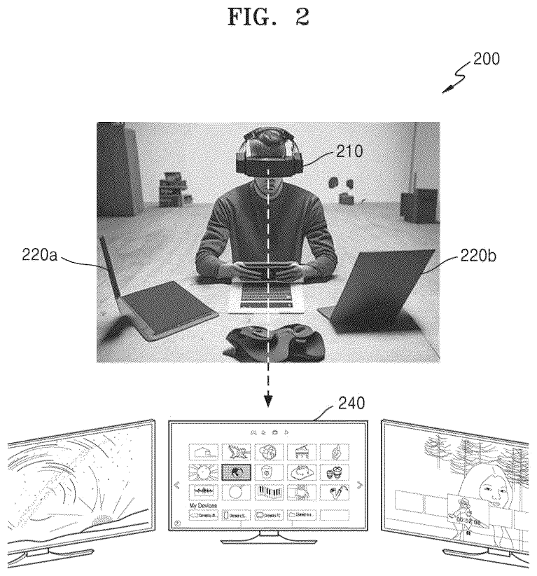

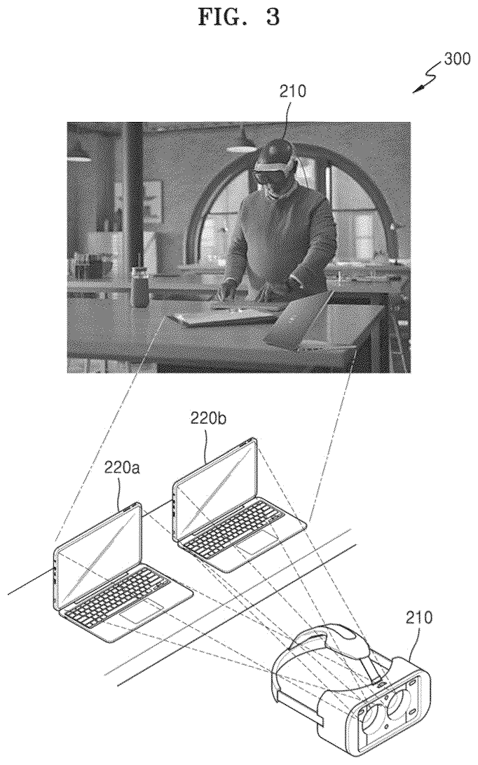

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein can be practiced and to further enable those of skill in the art to practice the embodiments herein. Accordingly, the examples should not be construed as limiting the scope of the embodiments herein.

In the disclosure, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the particular forms disclosed, but on the contrary, the disclosure is to cover all modifications, equivalents, and alternative falling within the scope of the disclosure.

The terms “comprises”, “comprising”, or any other variations thereof, are intended to cover a non-exclusive inclusion, such that a setup, device or method that comprises a list of components or operations does not include only those components or operations but may include other components or operations not expressly listed or inherent to such setup or device or method. In other words, one or more elements in a device or system or apparatus proceeded by “comprises . . . a” does not, without more constraints, preclude the existence of other elements or additional elements in the device or system or apparatus.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

For the purposes of interpreting this specification, the definitions (as defined herein) will apply and whenever appropriate the terms used in singular will also include the plural and vice versa. It is to be understood that the terminology used herein is for the purposes of describing particular embodiments only and is not intended to be limiting. The terms “comprising”, “having” and “including” are to be construed as open-ended terms unless otherwise noted.

The words/phrases “exemplary”, “example”, “illustration”, “in an instance”, “and the like”, “and so on”, “etc.”, “etcetera”, “e.g.,”, “i.e.,” are merely used herein to mean “serving as an example, instance, or illustration.” Any embodiment or implementation of the present subject matter described herein using the words/phrases “exemplary”, “example”, “illustration”, “in an instance”, “and the like”, “and so on”, “etc.”, “etcetera”, “e.g.,”, “i.e.,” is not necessarily to be construed as preferred or advantageous over other embodiments.

Embodiments herein may be described and illustrated in terms of blocks which carry out a described function or functions. These blocks, which may be referred to herein as managers, units, modules, engines (such as a pulse width modulation (PWM) detection engine, a device identification engine, and an action recommender engine), hardware components or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

It should be noted that elements in the drawings are illustrated for the purposes of this description and ease of understanding and may not have necessarily been drawn to scale. For example, the flowcharts/sequence diagrams illustrate the method in terms of the operations required for understanding of aspects of the embodiments as disclosed herein. Furthermore, in terms of the construction of the device, one or more components of the device may have been represented in the drawings by conventional symbols, and the drawings may show only those specific details that are pertinent to understanding the present embodiments so as not to obscure the drawings with details that will be readily apparent to those of ordinary skill in the art having the benefit of the description herein. Furthermore, in terms of the system, one or more components/modules which comprise the system may have been represented in the drawings by conventional symbols, and the drawings may show only those specific details that are pertinent to understanding the present embodiments so as not to obscure the drawings with details that will be readily apparent to those of ordinary skill in the art having the benefit of the description herein.

The accompanying drawings are used to help easily understand various technical features and it should be understood that the embodiments presented herein are not limited by the accompanying drawings. As such, the present disclosure should be construed to extend to any modifications, equivalents, and substitutes in addition to those which are particularly set out in the accompanying drawings and the corresponding description. Usage of words such as first, second, third etc., to describe components/elements/operations is for the purposes of this description and should not be construed as sequential ordering/placement/occurrence unless specified otherwise.

The term “couple” and the derivatives thereof refer to any direct or indirect communication between two or more elements, whether or not those elements are in physical contact with each other. The terms “transmit”, “receive”, and “communicate” as well as the derivatives thereof encompass both direct and indirect communication. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

The terms “IoT devices” and “display device” are used interchangeably in the patent disclosure. The terms “video see-through (VST) device” and “extended reality (XR) device” are used interchangeably in the patent disclosure.

It should be appreciated that the blocks in each flowchart and combinations of the flowcharts may be performed by one or more computer programs which include computer-executable instructions. The entirety of the one or more computer programs may be stored in a single memory or the one or more computer programs may be divided with different portions stored in different multiple memories.

Provided are methods and XR devices for extracting pulse width modulation (PWM) signals emitted by display devices (or IoT device) using camera of the XR device, analyzing the PWM signal to identify an identifier (ID) of the display device and displaying the name of the display device.

Provided are methods and XR devices for generating one or more dialogs and one or more options for a user based on identified display device capabilities and displaying a state of the display device.

Provided are methods and XR devices for adapting states of a light emitting diode (LED) to generate a pulse width modulated signal unique to a display device (e.g., LED display device).

Provided are methods and XR devices for capturing a Field of view (FOV) of the XR device and determine locations of pixel groups representative of each display device and extract PWM signals emitted by the display devices.

Provided are methods and XR devices for extracting the PWM signals emitted by the display device by locating pixel groups representative of the display device.

Provided are methods and XR devices for identifying the ID of the display device and name by determining unique parameters of PWM signal detected from the display device.

These and other aspects of the embodiments herein will be better appreciated and understood when considered in conjunction with the following description and the accompanying drawings. The following descriptions, while indicating at least one embodiment and numerous specific details thereof, are given by way of illustration and not of limitation. Many changes and modifications may be made within the scope of the embodiments herein without departing from the spirit thereof, and the embodiments herein include all such modifications.

Accordingly, the embodiments herein provide a method for handling a display device in an XR environment. The method includes obtaining, by an XR device, at least one media of a scene, where the scene includes a plurality of display devices. Further, the method includes determining, by the XR device, at least one pixel group, where the at least one pixel group includes locations of the plurality of display devices in the at least one obtained media. Further, the method includes extracting, by the XR device, at least one parameter from the at least one determined pixel group, where the at least one parameter includes at least one of: a frequency and a duty cycle. Further, the method includes extracting, by the XR device, a PWM signal corresponding to a display device from the plurality of display devices based on the at least one extracted parameter. Further, the method includes recognizing, by the XR device, the display device from the plurality of display devices by correlating the at least one extracted PWM signal with a name of the display device stored in a memory of the XR device or an external entity (e.g., a centralized database, a server).

The methods may be used for at least one of identifying and controlling the display devices using the PWM detection and frequency analysis, when a user is wearing the XR device in a simple and effective manner by eliminating the confusion or potential mix-ups when multiple display devices are present in a same area (e.g., an office, a living room). This may result in improving the user experience.

The proposed method can be used to enable the user to perform simple interactions for controlling a particular display device by pointing towards the display device (that has to be controlled) when the user is wearing the XR device.

In an example, based on the proposed method, the user wearing the XR device in a pass-through mode wants to access their laptop's content. The XR device's PWM detection engine may identify the laptop's unique PWM signal and retrieves its device ID using a device identification engine of the XR device. An action recommender engine of the XR device may suggest actions based on the laptop's capabilities. The user selects a menu, for example, “Cast Laptop on the XR device.” The XR device's controller engine may initiate the connection and the smart things engine facilitates a casting process. The laptop's content may be mirrored onto the XR device's display, enabling seamless access and interaction for the user.

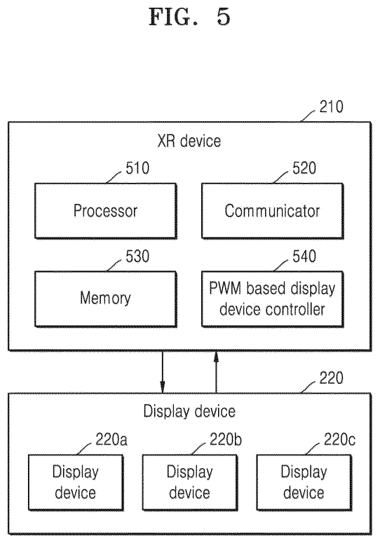

Referring now to the drawings, and more particularly, to FIGS. 5 through 16, where similar reference characters denote corresponding features consistently throughout the figures, there are shown at least one embodiment.

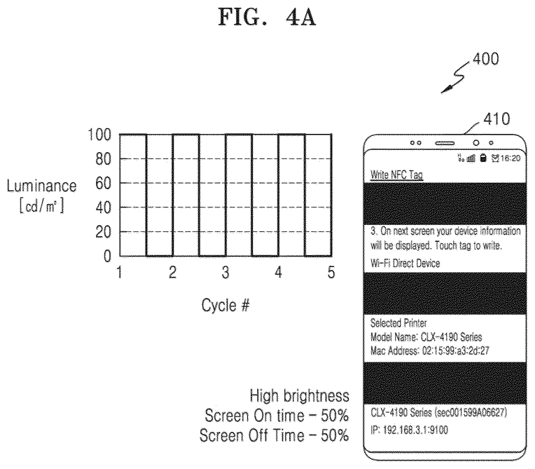

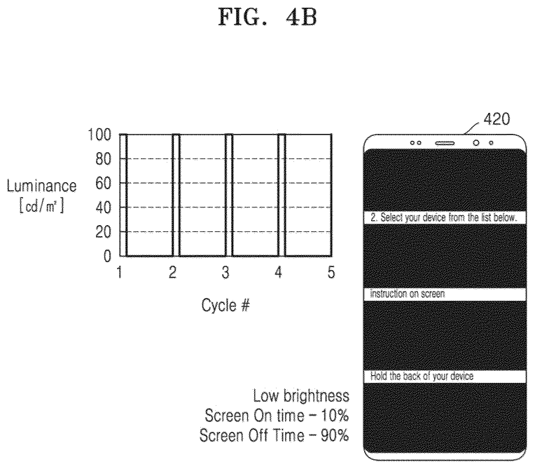

FIG. 4A and FIG. 4B illustrate how modern displays adjust their brightness. In an example, liquid crystal displays (LCDs) and organic light-emitting diodes (OLED) displays include light-emitting diodes, because of a diode's intrinsic physical properties, it cannot be dimmed by changing the intensity of the current, without impacting the color of light. One example method is to use a technique called pulse width modulation (PWM), which means that diodes are turned OFF and ON at varying rates. The PWM may be used to control the intensity of the light output by the LED. By varying the duty cycle of the PWM signal, the brightness of the LED can be adjusted. This switching between OFF and ON may be not visible to the human eye, as human brains perceive the screen as simply dimmer overall (a phenomenon known as the “brain averaging effect”). The level of brightness depends on how long the diodes are OFF versus how long they are ON. The longer they're OFF, the dimmer the screen will appear. Continuous switching ON and OFF of the LED results in black bands appearing on the screen, usually moving from top to bottom, but they may be in any orientation.

In an example, a mobile screen with the high brightness (410) in the slow-motion is shown in FIG. 4A and the mobile screen with the low brightness (420) in the slow-motion is shown in FIG. 4B.

FIG. 5 shows various hardware components of an XR device 210, according to the embodiments as disclosed herein. The XR device 210 may be, for example, but not limited to a VST device, an Augmented Reality (AR) device, a Mixed Reality (MR) device, a Virtual Reality (VR) device, an immersive device, and a metaverse device. In an embodiment, the XR device 210 may include a processor 510, a communicator 520, a memory 530 and a PWM based display device controller 540. The processor 510 is coupled with the communicator 520, the memory 530 and the PWM based display device controller 540. In an embodiment, the processor 510 may correspond to one or more processors. In an embodiment, the communicator 520 may correspond to one or more communication related circuits or codes (or their combinations) (such as a transmitter/a receiver). In an embodiment, the PWM based display device controller 540 may correspond to one or more processors. In an embodiment, the memory 530 may correspond to one or more memory devices.

The operations described below as being performed by the PWM-based display device controller (540) may also be performed by the processor (510) or a combination of the processor (510) and the PWM-based display device controller (540).

The PWM based display device controller (540) comprises hardware, such as at least one processor including processing circuitry. As used herein, the “at least one processor” may or may not be the same as the processor (510). If the processor (510) and the PWM-based display device controller (540) are the same, the processor (510) and the PWM-based display device controller (540) may be integrated as a single component.

In an embodiment, the PWM based display device controller 540 is configured to obtain a media of a scene, where the scene includes a plurality of display devices 220a-220c. Hereafter, the reference numeral for the display device is 220. The display device 220 may be, for example, but not limited to a laptop, a desktop computer, a notebook, a device-to-device (D2D) device, a vehicle to everything (V2X) device, a smartphone, a foldable phone, a smart TV, a tablet, a server, and an IoT device. The media of the scene including the display device from the plurality of display devices 220 may be obtained when a state of a lighting device generates the pulse width modulated signal unique to the display device from the plurality of display devices 220. In an embodiment, the PWM based display device controller 540 is configured to determine a pixel group. The pixel group includes locations of the plurality of display devices 220 in the obtained media. In an embodiment, the PWM based display device controller 540 is configured to identify a region of interest (RoI) corresponding to the display devices 220 by analyzing a temporal variation in a pixel intensity of the media. In an embodiment, the PWM based display device controller 540 is configured to determine the pixel group representing the display device from the plurality the locations in the media.

In an embodiment, the PWM based display device controller 540 is configured to determine a parameter based on the determined pixel group. The parameter may include at least one of a frequency and a duty cycle. The parameter may be determined by measuring the time interval between consecutive high and low states of the extracted PWM signal.

In an embodiment, the PWM based display device controller 540 is configured to extract a PWM signal corresponding to the display device from the plurality of display devices 220 based on the at least one extracted parameter. In an embodiment, the PWM signal is extracted from the pixel group by processing the obtained media to enhance the visibility and clarity of the display device, mapping the processed media onto a grid to spatially organize the display device present in a field of view (FOV), and analyzing the mapped grid for locating the pixels to extract PWM signal. In an embodiment, the PWM signal is extracted by analyzing temporal variations in pixel intensity in the pixel group. In a embodiment, the PWM signal is extracted after applying a noise filtering technique on the PWM signal to remove a noise or artifact.

In an embodiment, the PWM based display device controller 540 is configured to recognize the display device from the plurality of display devices 220 by correlating the extracted PWM signal with a name of the display device stored in a memory 530 of the XR device 210. The name of the display device from the plurality of display devices 220 is stored in the memory 530 or an external entity (e.g., a centralized database, a server) by a specific frequency value and a hash value representation indicating an identifier for the display device from the plurality of display devices 220.

In an embodiment, the PWM based display device controller 540 is configured to perform an action based on a user input and a defined input. The defined input means configured input by the user or a device end itself or from an OEM end. The action may include controlling the display device and interacting with the display device. In an embodiment, the PWM based display device controller 540 is configured to interact with the memory 530 storing a mapping between an ID and the display device from the plurality of display devices 220. In an embodiment, the PWM based display device controller 540 is configured to query the memory 530 using the ID to retrieve information of the display device from the plurality of display devices 220. In an embodiment, the PWM based display device controller 540 is configured to retrieve a device name, a manufacturer information, and a metadata for further processing to enable a suitable identification and association of the display device from the plurality of display devices 220 based on the ID. In an embodiment, the PWM based display device controller 540 is configured to perform the action based on the device name, the manufacturer information, and the metadata.

In an embodiment, the PWM based display device controller 540 is configured to detect the PWM signal associated with the display device using an imaging device (e.g., a camera) on the XR device 210 while monitoring the display device after activating a pass-through mode on the XR device 210. The pass-through mode allows the XR device to collect the identifier of the display device from the plurality of display devices by using the detected PWM signal. In an embodiment, the PWM based display device controller 540 is configured to obtain the ID of the display device from the plurality of display devices 220 from the memory 530 based on the detected PWM signal. In an embodiment, the PWM based display device controller 540 is configured to obtain a status of the display device and a capability of the display device based on the obtained identifier of the display device. Based on the status of the display device and the capability of the display device, the PWM based display device controller 540 is configured to perform the action. The action may include controlling the display device and interacting with the display device.

In an embodiment, the PWM based display device controller 540 is configured to scan an environment (e.g., IoT environment) in which a display device from a plurality of display devices 220 is located to emit the PWM signal, when the user of the XR device 210 approaches an area in which the display device is located while wearing the XR device 210. In an embodiment, the PWM based display device controller 540 is configured to detect the PWM signal emitted by the display device based on the scanning. In an embodiment, the PWM based display device controller 540 is configured to compare the detected PWM signal with a stored PWM signal in the memory 530 of the XR device 210 to determine an ID corresponding to the display device from the plurality of display devices 220. In an embodiment, the PWM based display device controller 540 is configured to perform the action. The action may include controlling the display device and interacting with the display device. The action may be performed by presenting a virtual control interface to the user to provide the user input and performing the action based on the user input. In an embodiment, the PWM based display device controller 540 is configured to provide a visual and auditory feedback to the user confirming the user action.

In an example, where the user of the XR device 210 is controlling a smart light, when the user uses the XR device 210. Consider that the user enters a room or approaches an area with smart lights while wearing the XR device 210. The XR device 210 activates its smart light control mode and scans the environment for smart lights emitting PWM frequencies. As the user gazes or points towards a specific smart light, the XR device 210 may detect the unique PWM frequency emitted by that light, allowing for identification. The XR device 210 may compare the detected PWM frequency with the stored database of smart light IDs to determine the specific light's unique ID. In an embodiment, the XR device 210 may determine the specific light's unique ID by comparing the detected PWM frequency with the stored database of smart light IDs to determine the specific light's unique ID. Once the smart light's ID is identified, the XR device 210 may present a virtual control interface or menu to the user, overlaying a real-world view. The user may select, a command as “Turn off this light” option. The XR device 210 sends the command to the smart light system and instructs the identified smart light with the corresponding unique ID to turn OFF. A smart light system may receive the command and processes it, turning OFF the targeted smart light. The XR device 210 provides visual and auditory feedback to the user about confirming the successful action of turning OFF the smart light. The user may repeat the process to control other smart lights in the environment, as needed.

The PWM based display device controller 540 may be implemented by analog and/or digital circuits such as logic gates, integrated circuits, microprocessors, microcontrollers, memory circuits, passive electronic components, active electronic components, optical components, hardwired circuits and the like, and may optionally be driven by firmware.

The processor 510 may include one or a plurality of processors. The one or the plurality of processors may be a general-purpose processor, such as a central processing unit (CPU), an application processor (AP), or the like, a graphics-only processing unit such as a graphics processing unit (GPU), a visual processing unit (VPU), and/or an AI-dedicated processor such as a neural processing unit (NPU). The processor 510 may include multiple cores and is configured to execute the instructions stored in the memory 530.

In an embodiment, the processor 510 is configured to execute instructions stored in the memory 530 and to perform various processes. The communicator 520 is configured for communicating internally between internal hardware components and with external devices via one or more networks. The memory 530 also stores instructions to be executed by the processor 510. The memory 530 may include non-volatile storage elements. Examples of such non-volatile storage elements may include magnetic hard discs, optical discs, floppy discs, flash memories, or forms of electrically programmable memories (EPROM) or electrically erasable and programmable (EEPROM) memories. In an embodiment, the memory 530 may, in some examples, be considered a non-transitory storage medium. The term “non-transitory” may indicate that the storage medium is not embodied in a carrier wave or a propagated signal. However, the term “non-transitory” should not be interpreted that the memory 530 is non-movable. In certain examples, a non-transitory storage medium may store data that can, over time, change (e.g., in Random Access Memory (RAM) or cache).

Although FIG. 5 shows various hardware components of the XR device 210 but it is to be understood that other embodiments are not limited thereon. In other embodiments, the XR device 210 may include less or more number of components. Further, the labels or names of the components are used only for illustrative purposes and does not limit the scope of the invention. One or more components can be combined together to perform the same or substantially similar function in the XR device 210.

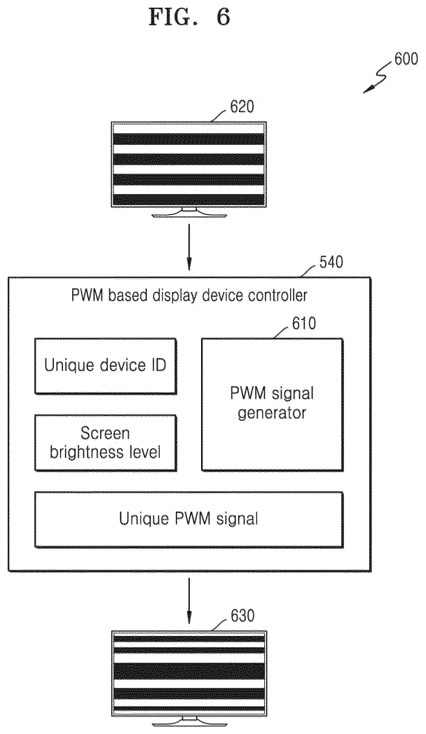

FIG. 6 illustrates an example scenario (600) in which the screen with the unique PWM signal is explained, according to the embodiments as disclosed herein. As depicted in FIG. 6, the PWM is a technique used to control the intensity of the light output by the LED. By varying the duty cycle of the PWM signal, the brightness of the LED can be adjusted. The processor 510 or a PWM signal generator 610 included in the PWM based display device controller 540 may be used to generate a different PWM signal for each device by assigning the unique pattern of ON and OFF times. A different combination of ON and OFF times can be used for each device to create a unique pattern that identifies it. In an embodiment, a combination of the processor 510 and a PWM signal generator 610 included in the PWM based display device controller 540 may be used to generate a different PWM signal for each device by assigning the unique pattern of ON and OFF times.

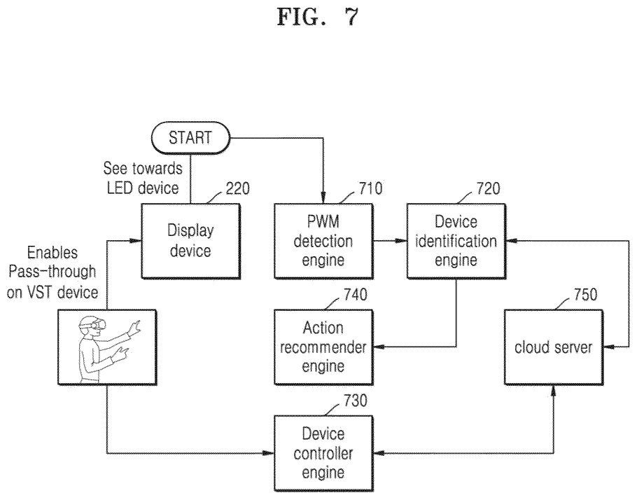

FIG. 7 shows various components of the PWM based display device controller 540 of the XR device 210 interacting with the display device (e.g., LED device) 220 and a cloud server 750, according to the embodiments as disclosed herein. In an embodiment, the PWM based display device controller 540 includes a PWM detection engine 710, a device identification engine 720, a device controller engine 730 and an action recommender engine 740.

The user of the XR device 210 may enable pass-through on the XR device (e.g., the VST device) 210 and sees towards the display device 220. The PWM detection engine 710 is configured to detect the PWM frequency of the display device using the imaging device (e.g., a camera) on the XR device 210. The device identification engine 720 is configured to fetch the device ID from the database using the unique PWM frequency. The cloud server 750 fetches the device status (e.g., power ON, Bluetooth Off, playing Music, downloading the video) and capabilities from the cloud server 750. The action recommender engine 740 recommends the actions to the user based on detected device capabilities and its status. The device controller engine 730 control the detected device. The device controller engine 730 may enable the user to control the device based on inputs from the user, where the user is looking at the device (that is being controlled).

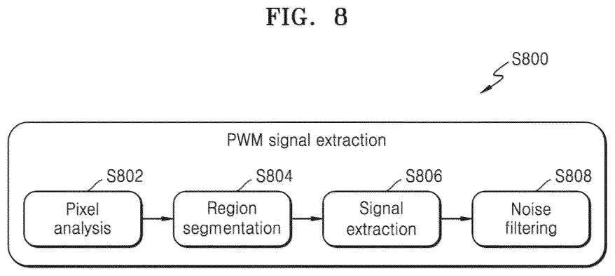

FIG. 8 is a flow chart (S800) illustrating a PWM signal extraction operation, according to the embodiments as disclosed herein.

At S802, in the pixel analysis, the PWM detection engine 710 is configured to analyze the pixel values of the captured (e.g. obtained) images to identify the regions of interest (RoI) corresponding to the LED display devices 220 (for example). The PWM detection engine 710 is configured to examine the intensity levels of the pixels to determine the presence of the display devices 220. At S804, in the region segmentation, once the regions of interest are identified, the PWM detection engine 710 is configured to perform region segmentation to isolate the LED regions from the rest of the image. This may be achieved through techniques like thresholding, edge detection, or contour analysis (for example). At S806, in the signal extraction, within each segmented LED region, the PWM signal and duty cycles are extracted by analyzing the temporal variations in pixel intensity (identifying the ON and OFF states of the LED). At S808, in noise filtering, the PWM detection engine 710 is configured to improve the accuracy of the extracted PWM signal by using a noise filtering techniques such as smoothing filters or statistical analysis (for example) that may be applied to remove any unwanted noise or artifacts.

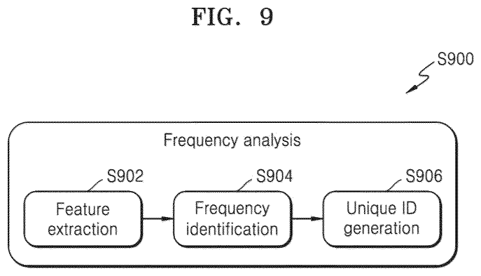

FIG. 9 is a flow chart (S900) illustrating a frequency analysis operation, according to the embodiments as disclosed herein

At S902, in the feature extraction, the PWM detection engine 710 is configured to combine the extracted features from different images to create a comprehensive representation of the LED device's unique PWM signature such pulse width and duty cycle. Pulse Width corresponds to duration of ON state and duty cycle represents the percentage of time the LED is ON within one period. At S904, in the frequency identification, by analyzing pattern, specific frequency peaks are identified, the PWM detection engine 710 is configured to indicate the unique frequency components of the PWM signal. At S906, unique ID generation, based on the identified frequency components, a unique ID is generated for each LED display device. This ID can be a combination of the specific frequency values or a hashed representation, serving as a unique identifier for device recognition and differentiation.

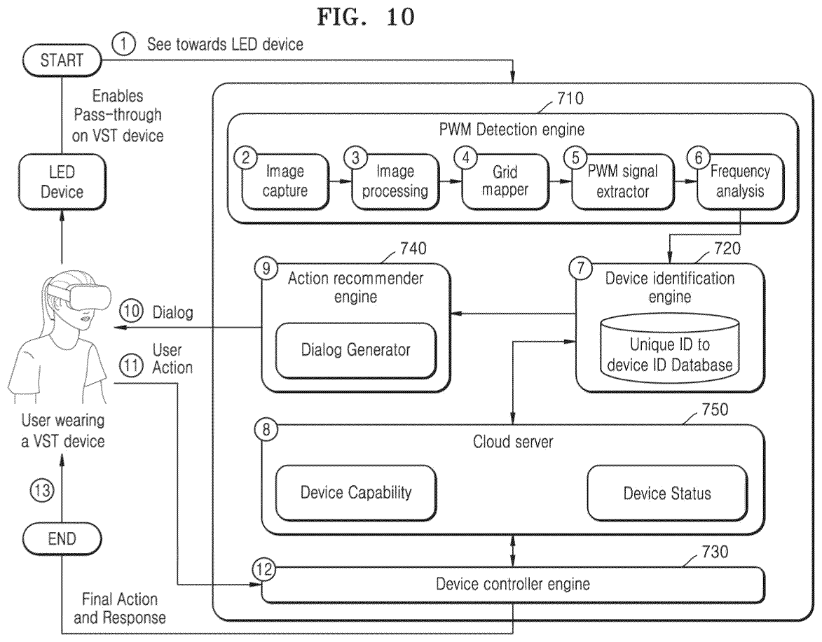

FIG. 10 illustrates a process of identifying and controlling the display devices 220 using the PWM detection and frequency analysis, when the user is wearing the XR device 210, according to the embodiments as disclosed herein. In operation 1, the user enables the pass-through on the XR device 210 and see or views towards the display device 220. In an embodiment, the user may see toward the LED based display devices. In operation 2, the XR (e.g. VST) camera(s) capture (e.g. obtain) the media (e.g., images/videos) of a surrounding view. In operation 3, the captured images are processed to enhance the visibility and clarity of the display devices 220 including the LED devices. In operation 4, the processed images are mapped onto a grid to spatially organize the display devices 220 present in the field of view. In operation 5, the mapped grid is analyzed to locate pixels where the PWM signals to extract PWM signals. In operation 6, for each detected PWM signal, the frequency of the signal is analyzed. In operation 7, the device-ID and the device name of the display device 220 are fetched from the memory 530. In operation 8, the device status and the device capabilities are fetched from the memory 530, a cloud system, a remote server and so on. In operation 9, the action recommender engine 740 generates one or more dialogs and options for the user based on the device capabilities and its status. In operation 10, the user receives the action dialog for performing the actions. In operation 11, the user gives the command to perform the actions. In operation 12, the device controller engine 730 controls the detected display device 220. In operation 13, the final action and response is given to the XR device 210 in the form of feedback.

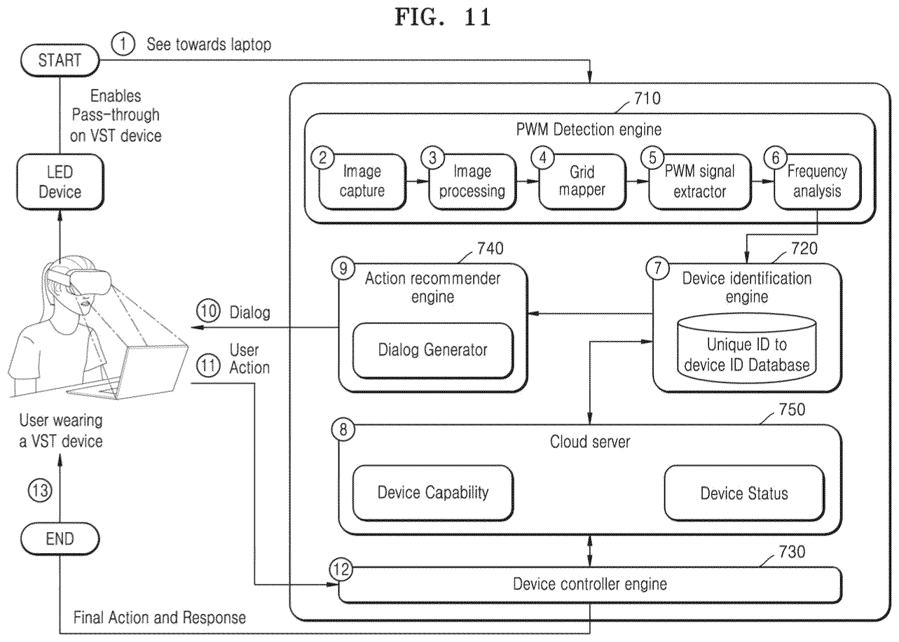

FIG. 11 illustrates a process of identifying and controlling the display devices (e.g., a laptop, a tablet, or a smart phone) using the PWM detection and frequency analysis, when the user is wearing the XR device 210 to access the display device 220, according to the embodiments as disclosed herein.

At operation 1, the user may see toward the LED based display devices 220 (e.g., a laptop, a tablet, or a smart phone). The PWM detection engine 710 is configured to detect the unique PWM signals emitted by the display devices 220. In an embodiment, the user may enable a pass-through on XR device 210. At operation 2, the PWM detection engine 710 is configured to obtain (e.g. capture) the captured photos or frames from the multiple cameras it has. Each camera captures a view of the surroundings including the display devices 220 emitting PWM signals. At operation 3, the captured (e.g. obtained) images are processed to enhance at least one of the visibility and clarity of the display devices 220. The image processing techniques like noise reduction, image enhancement, image resizing, and brightness/contrast adjustment (for example) may be applied to improve the accuracy of the PWM signal detection.

At operation 4, the processed images may be mapped onto the grid or a coordinate system. This mapping may help to spatially organize the display devices 220 present in the field of view. At operation 5, the mapped grid may be analyzed to locate areas or pixels where the PWM signals are present. Within each grid cell, the PWM detection engine 710 is configured to analyze the pixel values to extract the PWM signals emitted by the display devices 220. The PWM detection engine 710 is configured to identify the regions of interest where the LED pixels are present and extracts the corresponding PWM signals. This may be done by identifying specific characteristics or patterns associated with PWM signals, such as a frequency, a duty cycle, fluctuations in brightness or color.

At operation 6, for each detected PWM signal, the frequency of the signal is analyzed. This involves measuring the time intervals between consecutive high and low states of the signal and analyze the periodicity and frequency components of the PWM signals. At operation 7, by performing frequency analysis, the device identification engine 720 may identify the unique frequency associated with each display device 220. This unique frequency serves as an identifier or ID for the display device 220. In an embodiment, the device identification engine 720 may fetch the device ID and device name of display device 210 from the memory 530.

At operation 8, the device identification engine 720 may identify the device's ID and device name based on the unique ID obtained from the PWM detection engine 710. The device identification engine 720 may interact with a cloud server storing the mapping between unique IDs and the display devices 220. The device identification engine 720 may query the cloud server using the unique ID to retrieve associated device information. The device identification engine 720 may retrieve the device name, the manufacturer information, and the additional metadata for further processing or presentation. The device identification engine 720 may enable accurate identification and association of the display devices 220 based on their unique IDs. The device identification engine 720 facilitates effective control and interaction with the display devices 220. For example, the device identification engine 720 may identify the laptop device ID and device name from the memory 530.

At operation 9, the action recommender engine 740 utilizes the display device's current status and capabilities fetched from the cloud server or other sources (750). The action recommender engine 740 generates the dialog or provides recommendations for various actions (e.g., cast laptop on the XR device 210, power OFF laptop, pause music on the laptop) that can be performed on the display device 220. The action recommender engine 740 analyzes the device's current state, such as power status or media playback status. The action recommender engine 740 combines the current state with known capabilities to intelligently suggest actions to the user. The action recommender engine 740 presents recommendations through the user interface for the user to choose and initiate desired actions. The action recommender engine 740 enhances control, management, and interaction capabilities of the XR device 210. The action recommender engine 740 provides a seamless user experience and facilitates efficient device control and integration. In operation 10, the user receives the action dialog for performing the actions. In operation 11, the user gives the command to act the actions. In operation 12, the device controller engine 730 controls the detected device. In operation 13, the final action and response is given to the XR device 210.

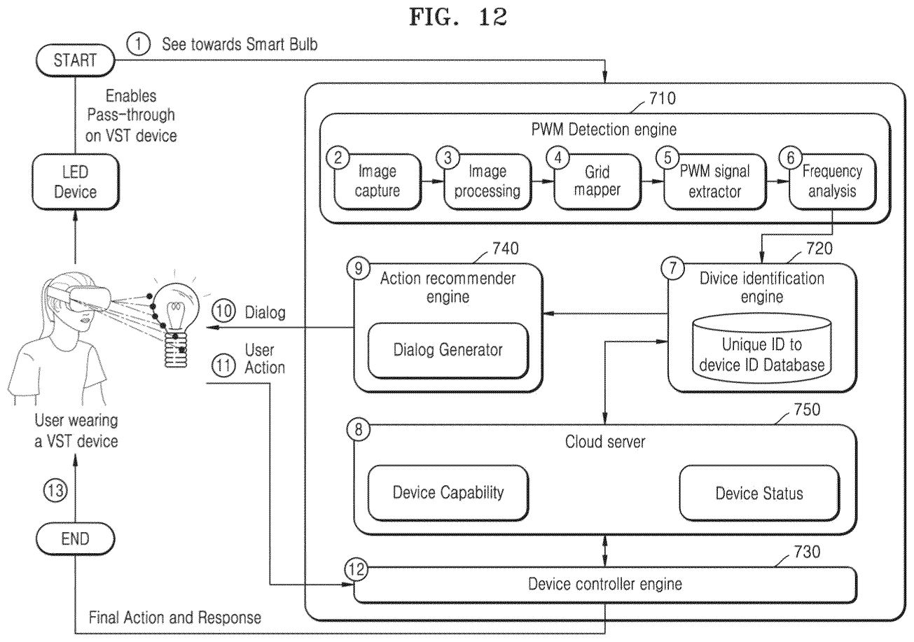

FIG. 12 illustrates a process of identifying and controlling the display devices 220 using the PWM detection and frequency analysis, when the user is wearing the XR device 210 to control the LED based display device (e.g., a smart bulb, a TV), according to the embodiments as disclosed herein.

At operation 1, the user may see toward the LED based display devices 220 (e.g., a smart bulb). The PWM detection engine 710 may detect the unique PWM signals emitted by the display devices 220. In an embodiment, the user may enable a pass-through on XR device 210. At operation 2, the PWM detection engine 710 obtains (e.g. capture) the photos or frames from each of the multiple cameras it has. Each camera captures a view of the surroundings, including the display devices 220 emitting the PWM signals. At operation 3, the obtained (e.g. captured) images are processed to enhance the visibility and clarity of the display devices 220.

At operation 4, the processed images may be mapped onto the grid or the coordinate system. This mapping may help to spatially organize the display devices 220 present in the field of view. At operation 5, the mapped grid may be analyzed to locate areas or pixels where the PWM signals are present. Within each grid cell, the PWM detection engine 710 may analyze the pixel values to extract the PWM signals emitted by the display devices 220. The PWM detection engine 710 may identify the regions of interest (RoI) where the LED pixels are present. The PWM detection engine 710 may extract the corresponding PWM signals. This is done by identifying specific characteristics or patterns associated with PWM signals, such as a frequency, a duty cycle, fluctuations in brightness or color, by the PWM detection engine 710.

At operation 6, for each detected PWM signal, the frequency of the signal may be analyzed. This involves measuring the time intervals between consecutive high and low states of the signal and analyze the periodicity and frequency components of the PWM signals. At operation 7, by performing frequency analysis, the device identification engine 720 may identify the unique frequency associated with each display devices 220. This unique frequency serves as an identifier or ID for the display devices 220. In an example, the device identification engine 720 may determine the bulb device ID and device name from the memory 530. In an embodiment, the device identification engine 720 may fetch the device ID and device name of display device 210 from the memory 530.

At operation 8, the device identification engine 720 may identify (e.g. fetch) the display device's ID and device name based on the unique ID obtained from the PWM detection engine 710. The device identification engine 720 may interact with the cloud server storing the mapping between unique IDs and the display devices 220. The device identification engine 720 may query the cloud server using the unique ID to retrieve associated device information. The device identification engine 720 retrieves the device name, the manufacturer information, and the additional metadata for further processing or presentation. The device identification engine 720 may enable accurate identification and association of the display devices 220 based on their unique IDs. The device identification engine 720 may facilitate effective control and interaction with the display devices 220.

At operation 9, the action recommender engine 740 may utilize the display device's current status and capabilities fetched from the cloud server or other sources. The action recommender engine 740 may generate the dialog or provides recommendations for various actions (e.g., turn OFF light, change color to blue, increase the brightness, or decrease the brightness) that can be performed on the device. The action recommender engine 740 may analyze the device's current state, such as power status, brightness level or the like. The action recommender engine 740 may combine the current state with known capabilities to intelligently suggest actions to the user. The action recommender engine 740 may present recommendations through the user interface for the user to choose and initiate desired actions. The action recommender engine 740 may enhance control, management, and interaction capabilities of the XR device 210. The action recommender engine 740 may provide the seamless user experience and facilitates efficient device control and integration. In operation 10, the user may receive (e.g. obtain) the action dialog for performing actions. In operation 11, the user may give the command to act for performing the actions. In operation 12, the device controller engine 730 may control the detected display device 220. In operation 13, the final action and response may be given to the XR device 210.

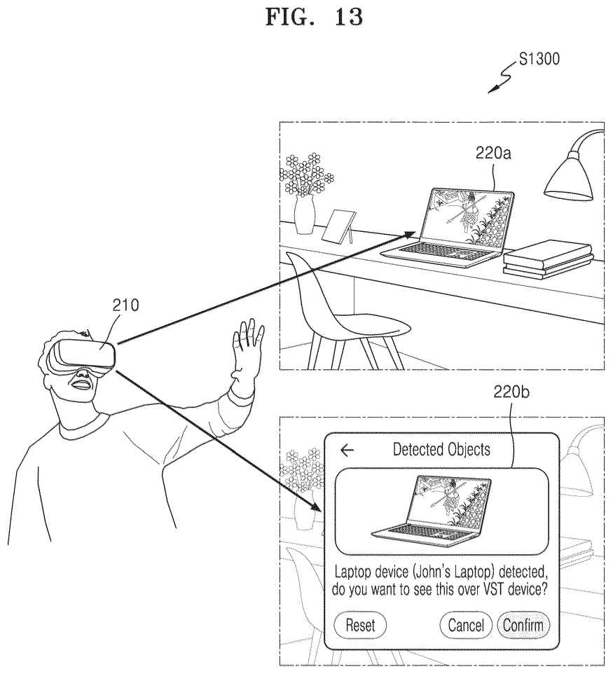

FIG. 13 depict an example scenario (1300), wherein the user controls the laptop or smart phone (220a and 220b), when the user wearing the XR device 210, according to the embodiments as disclosed herein. Once the user enters a room, the user can be presented with a prompt to check if the user wants to see the laptop (generally, detected object) over the XR device 210. In an embodiment, the user may have enabled the pass-through mode in the XR device 210. If the user wants (e.g. confirms, chooses) to see the laptop (generally, detected object) over the XR device 210, the screen of the laptop is casted onto the XR device 210. In an embodiment, XR device 210 may detect the laptop ID and its functions (e.g. capabilities) using PWM signal. In an embodiment, XR device 210 may prompt the user to take action on the laptop.

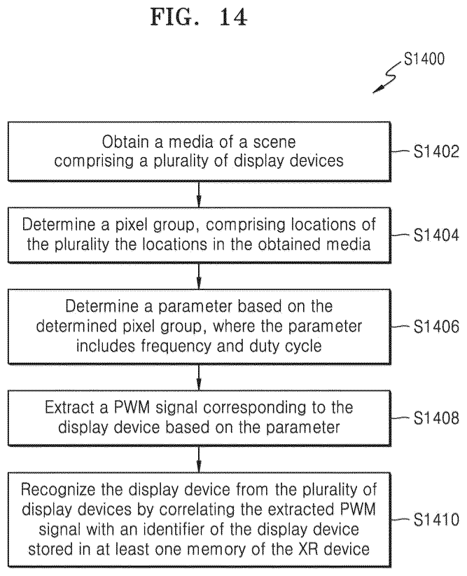

FIG. 14 is a flow chart (S1400) illustrating a method for handling the display device in the XR environment based on the extracted PWM signal, according to the embodiments as disclosed herein. The operations S1402-S1410 are handled by the PWM based display device controller 540. In an embodiment, the operations S1402-S1410 may be handled by the processor 510, or a combination of the processor 510 and the PWM based display device controller 540.

At S1402, the method includes obtaining the media of the scene comprising the plurality of display devices 220. At S1404, the method includes determining the pixel group. The pixel group includes locations of the plurality of display devices 220 in the obtained media. At S1406, the method includes determining the parameter based on the determined pixel group. The parameter may include at least one of the frequency and the duty cycle. At S1408, the method includes extracting the PWM signal corresponding to the display device from the plurality of display devices 220 based on the parameter. At S1410, the method includes recognizing the display device from the plurality of display devices 220 by correlating the extracted PWM signal with the identifier of the display device 220 stored in the at least one memory 530 of the XR device 210.

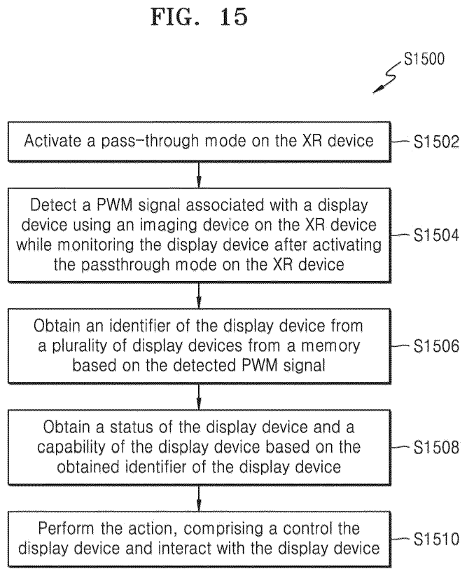

FIG. 15 is a flow chart (S1500) illustrating a method for handling the display device in the XR environment based on the pass-through mode, according to the embodiments as disclosed herein. The operations S1502-S1510 are handled by the PWM based display device controller 540. In an embodiment, the operations S1502-S1510 may be handled by the processor 510, or a combination of the processor 510 and the PWM based display device controller 540.

At S1502, the method includes activating the pass-through mode on the XR device 210. At S1504, the method includes detecting the PWM signal associated with the display device using the imaging device on the XR device 210 while monitoring the display device after activating the pass-through mode on the XR device 210. The pass-through mode allows the XR device to collect the identifier of the display device from the plurality of display devices by using the detected PWM signal. At S1506, the method includes obtaining the identifier of the display device from the plurality of display devices 220 from the memory 530 based on the detected PWM signal. At S1508, the method includes obtaining the status of the display device and the capability of the display device based on the obtained identifier of the display device. At S1510, the method includes performing the action. The action includes control the display device and interact with the display device.

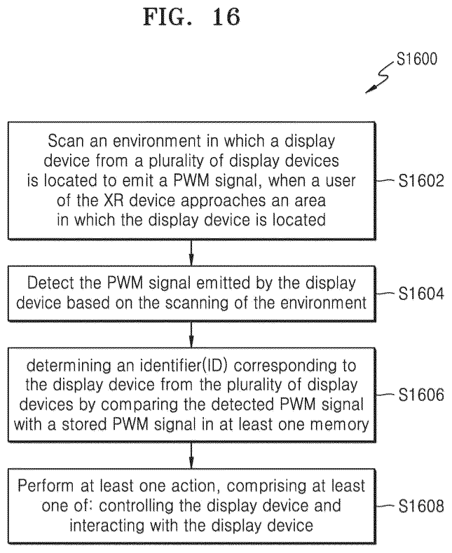

FIG. 16 is a flow chart (S1600) illustrating a method for handling the display device in the XR environment based on the detected PWM signal, according to the embodiments as disclosed herein. The operations S1602-S1608 are handled by the PWM based display device controller 540. In an embodiment, the operations S1602-S1608 may be handled by the processor 510, or a combination of the processor 510 and the PWM based display device controller 540.

At S1602, the method includes scanning the environment in which the display device from the plurality of display devices 220 is located to emit the PWM signal, when the user of the XR device 210 approaches the area in which the display device is located. At S1604, the method includes detecting the PWM signal emitted by the display device based on the scanning of the environment. At S1606, the method includes determining an identifier (ID) corresponding to the display device 210 from the plurality of display devices 220 by comparing the detected PWM signal with a stored PWM signal in at least one memory 530. At S1608, the method includes performing the action. The action includes controlling the display device and interacting with the display device.

The method can be used to simplify the process of identifying and controlling the display devices in a cost effective manner without user intervention. The method can be used to eliminate confusion or potential mix-ups when multiple display devices 220 are present in the same area (e.g., a living room, a hall, or a bedroom).

The various actions, acts, blocks, operations, or the like in the flow charts (S800, S900, S1400-S1600) may be performed in the order presented, in a different order or simultaneously. Further, in some embodiments, some of the actions, acts, blocks, operations, or the like may be omitted, added, modified, skipped, or the like without departing from the scope of the invention.

The embodiments disclosed herein can be implemented through at least one software program running on at least one hardware device and performing network management functions to control the elements. The elements can be at least one of a hardware device, or a combination of hardware device and software module.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of at least one embodiment, those skilled in the art will recognize that the embodiments herein can be practiced with modification within the spirit and scope of the embodiments as described herein.

According to an embodiment of the disclosure, a method for handling a display device in an extended reality (XR) environment is provided. The method may include obtaining, by an XR device, at least one media of a scene, wherein the scene comprises a plurality of display devices. The method may include determining, by the XR device, at least one pixel group, wherein the at least one pixel group comprises locations of the plurality of display devices in the at least one obtained media. The method may include determining, by the XR device, at least one parameter based on the at least one determined pixel group, wherein the at least one parameter comprises at least one of a frequency and a duty cycle. The method may include extracting, by the XR device, a pulse width modulation (PWM) signal corresponding to a display device from the plurality of display devices based on the at least one parameter. The method may include recognizing, by the XR device, the display device from the plurality of display devices by correlating the extracted PWM signal with a name of the display device stored in at least one memory of the XR device.

According to an embodiment of the disclosure, the method may include performing, by the XR device, at least one action based on at least one of: a user input and a predefined input. The at least one action may include at least one of: controlling the display device and interacting with the display device. According to an embodiment of the disclosure, the method may include performing, by the XR device, at least one action based on at least one of: a user input and a defined input.

According to an embodiment of the disclosure, performing, by the XR device, the at least one action may include fetching, by the XR device, a mapping between the ID and the display device from the plurality of display devices stored in at least one memory. Performing, by the XR device, the at least one action may include querying, by the XR device, the at least one memory using the ID to retrieve information of the display device from the plurality of display devices. Performing, by the XR device, the at least one action may include retrieving, by the XR device, at least one of a device name, a manufacturer information, and a metadata for processing to identify the display device from the plurality of display devices based on the ID. Performing, by the XR device, the at least one action may include performing, by the XR device, the at least one action based on at least one of the device name, the manufacturer information, and the metadata.

According to an embodiment of the disclosure, performing, by the XR device, the at least one action may include interacting, by the XR device with the at least one memory storing a mapping between an identifier (ID) and the display device from the plurality of display devices. Performing, by the XR device, the at least one action may include querying, by the XR device, the at least one memory using the ID to retrieve information of the display device from the plurality of display devices. Performing, by the XR device, the at least one action may include retrieving, by the XR device, a device name, a manufacturer information, and a metadata for further processing to enable a suitable identification and association of the display device from the plurality of display devices based on the ID. Performing, by the XR device, the at least one action may include performing, by the XR device, the at least one action based on the device name, the manufacturer information, and the metadata.

According to an embodiment of the disclosure, the determining, by the XR device, the at least one pixel group representing the display device from the plurality the locations in the at least one media may include identifying, by the XR device, a region of interest (RoI) corresponding to the display device by analyzing a temporal variation in a pixel intensity of the at least one media. Determining, by the XR device, the at least one pixel group representing the display device from the plurality the locations in the at least one media may include determining, by the XR device, the at least one pixel group representing the display device from the plurality the locations in the at least one media.

According to an embodiment of the disclosure, the extracting, by the XR device, the PWM signal may include extracting, by the XR device, the PWM signal from the at least one pixel group by processing the at least one obtained media. Extracting, by the XR device, the PWM signal may include mapping the at least one processed media onto a grid to spatially organize the display device present in a field of view (FOV). Extracting, by the XR device, the PWM signal may include analyzing the mapped grid for locating the pixels to extract the PWM signal.

According to an embodiment of the disclosure, the PWM signal may be extracted from the at least one pixel group by processing the at least one obtained media to enhance the visibility and clarity of the at least one display device. The PWM signal may be extracted from the at least one pixel group by mapping the at least one processed media onto a grid to spatially organize the display device present in a field of view (FOV). The PWM signal may be extracted from the at least one pixel group by analyzing the mapped grid for locating the pixels to extract the PWM signal.

According to an embodiment of the disclosure, the extracting, by the XR device, the PWM signal may include extracting, by the XR device, the PWM signal by analyzing temporal variations in pixel intensity in the at least one pixel group.

According to an embodiment of the disclosure, the pulse width modulation signal is extracted by analyzing temporal variations in pixel intensity in the at least one pixel group.

According to an embodiment of the disclosure, the extracting, by the XR device, the PWM signal may include extracting, by the XR device, the PWM signal after applying a noise filtering technique on the PWM signal.

According to an embodiment of the disclosure, the pulse width modulation signal may be extracted after applying a noise filtering technique to remove a noise or artifact on the pulse width modulation signal.

According to an embodiment of the disclosure, the determining, by the XR device, the at least one parameter comprises determining, by the XR device, the at least one parameter by measuring a time interval between high and low states of the PWM signal.

According to an embodiment of the disclosure, the at least one parameter is determined by measuring a time interval between consecutive high and low states of the extracted pulse width modulated signal.

According to an embodiment of the disclosure, the D of the display device from the plurality of display devices is stored in the at least one memory by at least one of a frequency value and a hash value representation.

According to an embodiment of the disclosure, the name of the display device from the plurality of display devices is stored in the at least one memory by at least one of a specific frequency value and a hash value representation indicating an identifier for the display device from the plurality of display devices.

According to an embodiment of the disclosure, obtaining at least one media of the scene comprising the display device from the plurality of display devices may include generating the PWM signal unique to the display device from the plurality of display devices by at least one state of a lighting device.

According to an embodiment of the disclosure, at least one media of the scene comprising the display device from the plurality of display devices is obtained when at least one state of a lighting device to generate the PWM signal unique to the display device from the plurality of display devices.

According to an embodiment of the disclosure, before the extracting, by the XR device, the PWM signal corresponding to the display device may include monitoring, by the XR device, the display device after activating a pass-through mode on the XR device.

According to an embodiment of the disclosure, a method for handling a display device in an extended reality (XR) environment is provided. The method may include detecting, by an XR device, a pulse width modulation (PWM) signal associated with a display device using an imaging device on the XR device while when monitoring, by the XR device, the display device after activating a pass-through mode on the XR device. The method may include obtaining, by the XR device, an identifier (ID) of the display device from a plurality of display devices from at least one memory based on the detected PWM signal. The method may include obtaining, by the XR device, at least one of: a status of the display device and a capability of the display device based on the obtained identifier of the display device. The method may include performing, by the XR device, at least one action, wherein the at least one action comprises comprising at least one of: controlling the display device and interacting with the display device.

According to an embodiment of the disclosure, in the pass-through mode, the XR device may be configured to collect an identifier (ID) of the display device from the plurality of display devices by using the extracted PWM signal.

According to an embodiment of the disclosure, a method for handling a display device in an extended reality (XR) environment is provided. The method may include scanning, by an XR device, an environment in which a display device from a plurality of display devices is located to emit a pulse width modulation (PWM) signal, when a user of the XR device approaches an area in which the display device is located while wearing the XR device. The method may include scanning, by an XR device, an environment in which a display device from a plurality of display devices is located to emit a pulse width modulation (PWM) signal, when a user of the XR device approaches an area in which the display device is located. The method may include detecting, by the XR device, the PWM signal emitted by the display device based on the scanning of the environment. The method may include determining an identifier (ID) corresponding to the display device from the plurality of display devices by comparing, by the XR device, the detected PWM signal with a stored PWM signal in the at least one memory of the XR device to determine an identifier (ID) corresponding to the display device from the plurality of display devices. The method may include performing, by the XR device, at least one action, wherein the at least one action comprises at least one of: controlling the display device and interacting with the display device.

According to an embodiment of the disclosure, performing, by the XR device, at least one action may include presenting, by the XR device, a virtual control interface to the user to provide a user input. Performing, by the XR device, at least one action may include performing, by the XR device, the at least one action based on the user input.

According to an embodiment of the disclosure, performing, by the XR device, at least one action based on at least one of a user input and a defined input may include presenting, by the XR device, a virtual control interface to the user to provide a user input. Performing, by the XR device, at least one action based on at least one of a user input and a defined input may include performing, by the XR device, the at least one action based on the user input.

According to an embodiment of the disclosure, the method may include providing, by the XR device, a visual and auditory feedback to the user confirming the user action.

According to an embodiment of the disclosure, an extended reality (XR) device is provided. The XR device may include a processor. The XR device may include a memory. The XR device may include a PWM based display device controller, coupled with the processor and the memory, configured to cause the XR device to obtain at least one media of a scene wherein the media comprises a plurality of display devices. The XR device may include a PWM based display device controller, coupled with the processor and the memory, configured to cause the XR device to determine at least one pixel group wherein the at least one pixel group comprises locations of the plurality the locations in the at least one obtained media. The XR device may include a PWM based display device controller, coupled with the processor and the memory, configured to cause the XR device to determine at least one parameter based on the at least one determined pixel group, wherein the at least one parameter comprises at least one of a frequency and a duty cycle. The XR device may include a PWM based display device controller, coupled with the processor and the memory, configured to cause the XR device to extract a pulse width modulation (PWM) signal corresponding to the display device from the at least one parameter. The XR device may include a PWM based display device controller, coupled with the processor and the memory, configured to cause the XR device to recognize the display device from the plurality of display devices by correlating the extracted PWM signal with a name of the display device stored in the memory of the XR device.

According to an embodiment of the disclosure, an extended reality (XR) device is provided. The XR device may include at least one processor. The XR device may include at least one a memory. The XR device may include a pulse width modulation (PWM) based display device controller, coupled with the at least one processor and the at least one memory, configured to activate a pass-through mode on the XR device. The XR device may include a pulse width modulation (PWM) based display device controller, coupled with the at least one processor and the at least one memory, configured to detect a pulse width modulation (PWM) signal associated with a display device using an imaging device on the XR device when monitoring the display device after activating the pass-through mode on the XR device. The XR device may include a pulse width modulation (PWM) based display device controller, coupled with the at least one processor and the at least one memory, configured to obtain an identifier (ID) of the display device from a plurality of display devices from the at least one memory based on the detected PWM signal. The XR device may include a pulse width modulation (PWM) based display device controller, coupled with the at least one processor and the at least one memory, configured to obtain at least one of: a status of the display device and a capability of the display device based on the obtained identifier of the display device. The XR device may include a pulse width modulation (PWM) based display device controller, coupled with the at least one processor and the at least one memory, configured to perform at least one action, wherein the at least one action comprising at least one of: controlling the display device and interacting with the display device.

According to an embodiment of the disclosure, an extended reality (XR) device is provided. The XR device may include at least one processor. The XR device may include at least one a memory. The XR device may include a pulse width modulation (PWM) based display device controller, coupled with the at least one processor and the at least one memory, configured to scan an environment in which a display device from a plurality of display devices is located to emit a pulse width modulation (PWM) signal, when a user of the XR device approaches an area in which the display device is located while wearing the XR device. The XR device may include a pulse width modulation (PWM) based display device controller, coupled with the at least one processor and the at least one memory, configured to detect the PWM signal emitted by the display device based on the scanning of the environment. The XR device may include a pulse width modulation (PWM) based display device controller, coupled with the at least one processor and the at least one memory, configured to determine an identifier (ID) corresponding to the display device from a plurality of display devices by comparing the detected PWM signal with the stored PWM signal in the memory (530) at least one memory of the XR device to determine an identifier (ID) corresponding to the display device from a plurality of display devices. The XR device may include a pulse width modulation (PWM) based display device controller, coupled with the at least one processor and the at least one memory, configured to perform at least one action, wherein the at least one action comprising at least one of: control the display device and interact with the display device.

What is claimed is:

1. A method for handling a display device in an extended reality (XR) environment, comprising:
obtaining, by an XR device, at least one media of a scene comprising a plurality of display devices;
determining, by the XR device, at least one pixel group comprising locations of the plurality of display devices in the at least one media;
determining, by the XR device, at least one parameter based on the at least one determined pixel group, wherein the at least one parameter comprises at least one of a frequency and a duty cycle;
extracting, by the XR device, a pulse width modulation (PWM) signal corresponding to the display device from the plurality of display devices based on the at least one parameter; and
recognizing, by the XR device, the display device from the plurality of display devices by correlating the extracted PWM signal with an identifier (ID) of the display device stored in at least one memory of the XR device.

2. The method of claim 1, further comprising performing, by the XR device, at least one action based on at least one of a user input and a defined input,
wherein the at least one action comprises at least one of controlling the display device and interacting with the display device.

3. The method of claim 2, wherein the performing, by the XR device, the at least one action comprises:
fetching, by the XR device, a mapping between the ID and the display device from the plurality of display devices stored in at least one memory;
querying, by the XR device, the at least one memory using the ID to retrieve information of the display device from the plurality of display devices;
retrieving, by the XR device, at least one of a device name, a manufacturer information, and a metadata for processing to identify the display device from the plurality of display devices based on the ID; and
performing, by the XR device, the at least one action based on at least one of the device name, the manufacturer information, and the metadata.

4. The method of claim 1, wherein the determining, by the XR device, the at least one pixel group representing the display device from the plurality the locations in the at least one media comprises:
identifying, by the XR device, a region of interest (RoI) corresponding to the display device by analyzing a temporal variation in a pixel intensity of the at least one media; and
determining, by the XR device, the at least one pixel group representing the display device from the plurality the locations in the at least one media.

5. The method of claim 1, wherein the extracting, by the XR device, the PWM signal comprises extracting, by the XR device, the PWM signal from the at least one pixel group by:
processing the at least one obtained media;
mapping the at least one processed media onto a grid to spatially organize the display device present in a field of view (FOV); and
analyzing the mapped grid for locating the pixels to extract the PWM signal.

6. The method of claim 1, wherein the extracting, by the XR device, the PWM signal comprises extracting, by the XR device, the PWM signal by analyzing temporal variations in pixel intensity in the at least one pixel group.

7. The method of claim 1, wherein the extracting, by the XR device, the PWM signal comprises extracting, by the XR device, the PWM signal after applying a noise filtering technique on the PWM signal.

8. The method of claim 1, wherein the determining, by the XR device, the at least one parameter comprises determining, by the XR device, the at least one parameter by measuring a time interval between high and low states of the PWM signal.

9. The method of claim 1, wherein the ID of the display device from the plurality of display devices is stored in the at least one memory by at least one of a frequency value and a hash value representation.

10. The method of claim 1, wherein the obtaining at least one media of the scene comprising the display device from the plurality of display devices comprises: generating the PWM signal unique to the display device from the plurality of display devices by at least one state of a lighting device.

11. The method of claim 1, wherein before the extracting, by the XR device, the PWM signal corresponding to the display device comprises:
monitoring, by the XR device, the display device after activating a pass-through mode on the XR device.

12. The method of claim 11, wherein, in the pass-through mode, the XR device is configured to collect an identifier (ID) of the display device from the plurality of display devices by using the extracted PWM signal.

13. The method of claim 1, wherein obtaining, by an XR device, at least one media of a scene comprising a plurality of display devices t, comprises:
scanning, by an XR device, an environment in which a display device from a plurality of display devices is located to emit a pulse width modulation (PWM) signal, when a user of the XR device approaches an area in which the display device is located.

14. The method of claim 13, further comprising detecting, by the XR device, the PWM signal emitted by the display device based on the scanning of the environment.

15. The method of claim 1, wherein the recognizing, by the XR device, the display device from the plurality of display devices comprises:
determining an identifier (ID) corresponding to the display device from the plurality of display devices by comparing, by the XR device, the detected PWM signal with a stored PWM signal in at least one memory of the XR device; and
performing, by the XR device, at least one action comprising at least one of controlling the display device and interacting with the display device.

16. The method of claim 2, wherein the performing, by the XR device, the at least one action based on at least one of a user input and a defined input comprises:
presenting, by the XR device, a virtual control interface to the user to provide a user input; and
performing, by the XR device, the at least one action based on the user input.

17. The method of claim 16, further comprising providing, by the XR device, a visual and auditory feedback to the user confirming the user action.

18. An extended reality (XR) device comprising:
at least one processor;
at least one memory; and
a pulse width modulation (PWM) based display device controller, coupled with the at least one processor and the at least one memory, configured to cause the XR device to:
obtain at least one media of a scene comprising a plurality of display devices;
determine at least one pixel group comprising locations of the plurality the locations in the at least one obtained media;
determine at least one parameter based on the at least one determined pixel group, wherein the at least one parameter comprises at least one of a frequency and a duty cycle;
extract a pulse width modulation (PWM) signal corresponding to the display device from the at least one parameter; and
recognize the display device from the plurality of display devices by correlating the extracted PWM signal with an identifier (ID) of the display device stored in the at least one memory of the XR device.

19. The XR device of claim 18, wherein the PWM based display device controller is configured to cause the XR device to:
monitor the display device after activating a pass-through mode on the XR device before extracting a PWM signal corresponding to the display device from the at least one parameter.

20. A non-transitory computer-readable storage medium storing instructions, wherein the instructions, when executed by at least one processor, cause the XR device to perform the method comprising:
obtaining, by an XR device, at least one media of a scene comprising a plurality of display devices;
determining, by the XR device, at least one pixel group comprising locations of the plurality of display devices in the at least one media;
determining, by the XR device, at least one parameter based on the at least one determined pixel group, wherein the at least one parameter comprises at least one of a frequency and a duty cycle;
extracting, by the XR device, a pulse width modulation (PWM) signal corresponding to the display device from the plurality of display devices based on the at least one parameter; and
recognizing, by the XR device, the display device from the plurality of display devices by correlating the extracted PWM signal with an identifier (ID) of the display device stored in at least one memory of the XR device.
